(19) United States
(12) Patent Application Publication
(10) Pub. No.: US 2025/0245096 A1
(43) Pub. Date: Jul. 31, 2025

(54) TRIGGERING LANE MARGINING

(71) Applicant: Micron Technology, Inc., Boise, ID (US)

(72) Inventors: Sandeep Arni, Hyderabad (IN); Ashutosh Shashikant Kondejkar, Pune (IN)

(21) Appl. No.: 19/020,955

(22) Filed: Jan. 14, 2025

Related U.S. Application Data
(60) Provisional application No. 63/627,560, filed on Jan. 31, 2024.

(51) Int. Cl. G06F 11/07; G06F 11/30

(52) U.S. Cl. CPC G06F 11/0793; G06F 11/0745; G06F 11/3041

(57) ABSTRACT

Methods, systems, and devices for triggering lane margining are described. A memory system controller may dynamically trigger the lane margining procedure based on a quantity of link recovery procedures performed at one or more input/output (I/O) ports established between a memory system and a host system. For example, the memory system controller may monitor, during a first duration, the performance of link recovery procedures performed at the one or more I/O ports. Based on a quantity of the link recovery procedures satisfying a threshold of link recovery procedures, the memory system controller may determine a rate of change between the quantity of link recovery procedures and a second quantity of link recovery procedures. If the rate of change between the quantity of link recovery procedures and the second quantity of link recovery procedures is increasing, the memory system controller may initiate the lane margining procedure.

### CROSS REFERENCE

The present Application for Patent claims priority to U.S. Patent Application No. 63/627,560 by Arni et al., entitled “TRIGGERING LANE MARGINING,” filed Jan. 31, 2024, which is assigned to the assignee hereof, and which is expressly incorporated by reference in its entirety herein.

### TECHNICAL FIELD

The following relates to one or more systems for memory, including triggering lane margining.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports triggering lane margining in accordance with examples as disclosed herein.

FIG. 2 shows an example of a process flow that supports triggering lane margining in accordance with examples as disclosed herein.

FIG. 3 shows a block diagram of a memory system that supports triggering lane margining in accordance with examples as disclosed herein.

FIG. 4 shows a flowchart illustrating a method or methods that support triggering lane margining in accordance with examples as disclosed herein.

### DETAILED DESCRIPTION

A memory system (e.g., a solid state drive (SSD)) may perform a lane margining procedure to identify reference voltages and sampling times used to read signals over one or more input/output (I/O) ports (e.g., egress ports and ingress ports) established between the memory system and a host system. For example, during the lane margining procedure, a memory system controller of the memory system may measure (e.g., identify or calculate) eye pattern information for a first I/O port, where such eye pattern information may include an eye width (e.g., a duration the eye spans within a single unit interval) and an eye height (e.g., voltage amplitude of the eye between different voltage levels). The memory system controller may determine whether the measured eye width satisfies a threshold eye width and whether the measured eye height satisfies a threshold eye height (e.g., whether the duration and voltage amplitude satisfy respective time and voltage thresholds for the I/O port). If the eye width or the eye height satisfy the respective thresholds, the memory system controller may identify a first reference voltage for the first I/O port based on the eye height and identify a first sampling time for the first I/O port based on the eye width information (e.g., the memory system controller may find the center of the eye, where the reference voltage corresponds to a center voltage of the eye height and the sampling time corresponds to a center time of the eye width).

The memory system controller may perform such operations to identify the respective reference voltages and sampling times for each I/O port established between the memory system and the host system. As such, the memory system controller may maintain accurate reference voltages and sampling times to read signals from the host system. In such cases, however, the memory system controller may perform the lane margining procedure ad hoc, for example, by performing the lane margining procedure in response to a failure (e.g., I/O timeout) or degraded performance across the I/O ports, rather than proactively performing the lane margining procedure to prevent such failures or degraded performance. Such ad hoc performance of the lane margining procedure may result in increased communication failures (e.g., I/O timeouts) over the one or more I/O ports. In some cases, the memory system controller may also perform such operations to identify the respective reference voltages and sampling times for each eye at each I/O port. For example, if a four-level pulse amplitude modulation scheme is used to signal information at the I/O port, the signaling may include three eyes.

The techniques, methods, and components described herein may enable the memory system controller to dynamically trigger the lane margining procedure, thereby preventing one or more failures or degraded communications over the one or more I/O ports (e.g., improve the link stability between the host system and the memory system). For example, the memory system controller may monitor (e.g., keep track of, account for), during a first duration (e.g., one or more unit intervals), the performance of link recovery procedures performed at the one or more I/O ports. As such, based on a first quantity of the link recovery procedures exceeding a threshold, the memory system controller may determine a rate of change between the first quantity of link recovery procedures and at least a second quantity of link recovery procedures. If the memory system controller determines that the rate of change between the first quantity of link recovery procedures and the at least second quantity of link recovery procedures is increasing (e.g., respective quantity of link recovery procedures captured between two or more unit intervals is increasing), then the memory system controller may initiate the lane margining procedure. By dynamically triggering the lane margining procedure based on a quantity of link recovery procedures, the memory system controller may proactively reduce the quantity of communication failures and I/O timeouts on the I/O ports, thereby improving the reliability of the link between the memory system and the host system.

In addition to applicability in memory systems as described herein, techniques for triggering lane margining may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by initiating lane margining procedures based on a quantity of link recovery procedures, which may improve the stability and quality of one or more I/O ports between the host system and the memory system, among other benefits.

Features of the disclosure are illustrated and described in the context of systems, devices, and circuits. Features of the disclosure are further illustrated and described in the context of flowcharts.

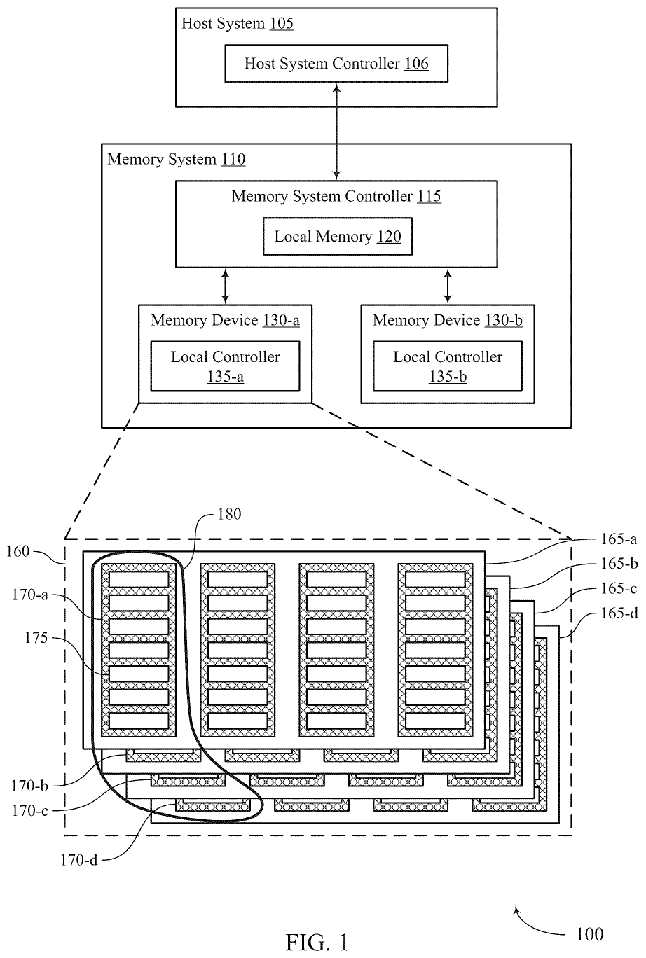

FIG. 1 shows an example of a system 100 that supports triggering lane margining in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a SSD, a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

The system 100 may include any quantity of non-transitory computer readable media that support triggering lane margining. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

In some examples, the memory system 110 (e.g., an SSD), via the memory system controller 115, may perform a lane margining procedure to identify reference voltages and sampling times used to read signals over one or more I/O ports established between the memory system 110 and the host system 105. For example, during the lane margining procedure, the memory system controller 115 may measure (e.g., identify or calculate) eye pattern information for a first I/O port, where such eye pattern information may include an eye width (e.g., a duration the eye spans within a single unit interval) and an eye height (e.g., voltage amplitude of the eye). The memory system controller 115 may determine whether the measured eye width satisfies a threshold eye width and whether the measured eye height satisfies a threshold eye height (e.g., whether the duration and voltage amplitude satisfy respective time and voltage thresholds for the I/O port). If the eye width or eye height satisfy the respective thresholds, the memory system controller 115 may identify a first reference voltage for the first I/O port based on the eye height and identify a first sampling time for the first I/O port based on the eye width information (e.g., the memory system controller 115 may find the center of the eye, where the reference voltage corresponds to a center voltage of the eye height and the sampling time corresponds to a center time of the eye width).

The memory system controller 115 may perform such operations to identify the respective reference voltages and sampling times for each I/O port established between the memory system and the host system 105. As such, the memory system controller 115 may maintain accurate reference voltages and sampling times to read signals from the host system 105. In such cases, however, the memory system controller 115 may perform the lane margining procedure ad hoc, for example, by performing the lane margining procedure in response to a failure (e.g., I/O timeout) or degraded performance across the I/O ports, rather than proactively performing the lane margining procedure to prevent such failures or degraded performance. Such ad hoc performance of the lane margining procedure may result in increased communication failures and degraded communication over the one or more I/O ports.

The techniques, methods, and components described herein may enable the memory system controller 115 to dynamically trigger the lane margining procedure, thereby preventing one or more failures or degraded communications over the one or more I/O ports (e.g., improve the link stability between the host system 105 and the memory system 110). For example, the memory system controller 115 may monitor (e.g., keep track of, account for), during a first duration (e.g., one or more unit intervals), the performance of link recovery procedures performed at the one or more I/O ports. As such, based on a first quantity of the link recovery procedures exceeding a threshold of link recovery procedures, the memory system controller 115 may determine a rate of change between the first quantity of link recovery procedures and a second quantity of link recovery procedures. If the memory system controller 115 determines that the rate of change between the first quantity of link recovery procedures and the second quantity of link recovery procedures is increasing (e.g., respective quantity of link recovery procedures captured between two durations is increasing), then the memory system controller 115 may initiate the lane margining procedure. By dynamically triggering the lane margining procedure based on a quantity of link recovery procedures, the memory system controller 115 may proactively reduce the quantity of I/O timeouts and prevent degraded communications on the I/O ports, thereby improving the reliability of the link between the memory system 110 and the host system 105.

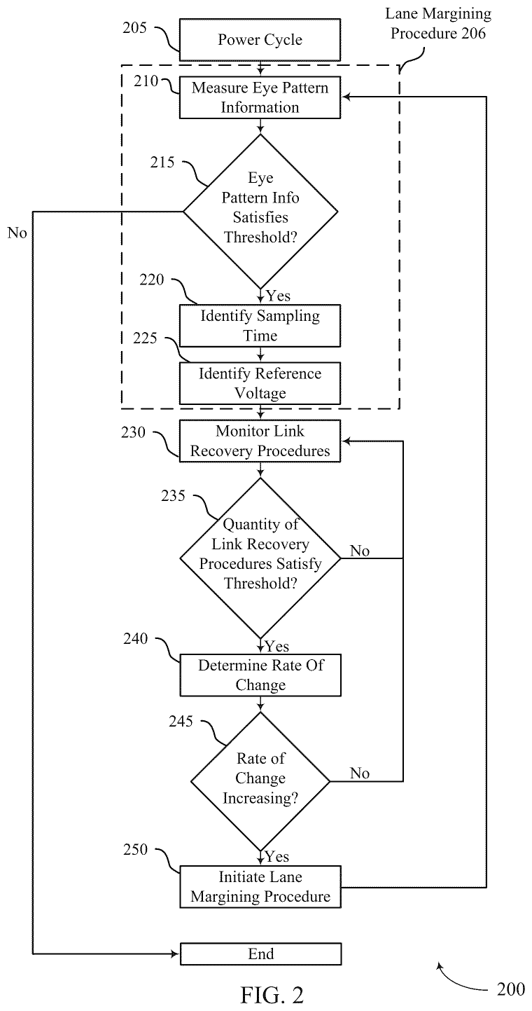

FIG. 2 shows an example of a process flow 200 that supports triggering lane margining in accordance with examples as disclosed herein. Aspects of the process flow 200 may be implemented by aspects of the system 100 as described herein with reference to FIG. 1. For example, the operations of the process flow 200 may be implemented as instructions (e.g., firmware, software, or the like) stored at a memory system (e.g., stored in local memory 120 of a memory system 110) and that are executable by a memory system controller (e.g., memory system controller 115). That is, the operations of the process flow 200 may be performed by the memory system controller. The techniques described in the context of the process flow 200 may enable the memory system controller to dynamically initiate a lane margining procedure 206.

A memory system (e.g., the memory system 110) may perform the lane margining procedure 206 to identify a reference voltage and a sampling time used to read signals over lanes of at least one I/O port (e.g., link) between the memory system and a host system (e.g., the host system 105). As described herein, a lane may be a set of differential signal pairs, where one pair may be used for transmission by the memory system and one pair may be used for reception at the memory system. An I/O port may be a group of transmitters and receivers at the memory system that, logically, are an interface between the memory system and the link between the memory system and the host system. A link may be a dual simplex communications path between two components, where the link may include two ports (e.g., a port at the memory system and a port at the host device) and the lanes that interconnect the two ports. For example, a by-N Link (also referred to as a by-N Port) may be a link that is composed of N lanes, where each lane may include a transmission and reception pair that are used to communicate signals between the memory system and the host system. In some examples, a lane may be a single conductive line configured for unidirectional communication or bidirectional communication between the memory system and the host system.

By performing the lane margining procedure 206, the memory system controller may maintain accurate reference voltages and sampling times to read signals from the host system. In such cases, however, the memory system controller may perform the lane margining procedure ad hoc, for example, by performing the lane margining procedure in response to a failure (e.g., I/O timeout) or degraded performance across the I/O ports, rather than proactively performing the lane margining procedure to prevent such failures or degraded performance. That is, currently, there are no mechanisms for triggering the lane margining procedure 206, which leads to ambiguous timing of the lane margining procedure 206. Accordingly, such ad hoc performance of the lane margining procedure may result in increased communication failures (e.g., increased I/O timeouts) over the one or more I/O ports.

In accordance with the techniques described herein, the memory system controller may be enabled to initiate the lane margining procedure 206 based on a quantity of link recovery procedures performed at the at least one I/O port established between the memory system and the host system.

At 205, the memory system may be power cycled. Based on the memory system being power cycled, the memory system controller may perform an initial iteration of the lane margining procedure 206 for the at least one I/O port.

At 210, the memory system controller may measure (e.g., stress) the at least one I/O port to obtain eye pattern information associated with at least one I/O port, where such eye pattern information may include at least an eye width (e.g., a time domain measurement) and an eye height (e.g., a voltage domain measurement). That is, the memory system controller may measure the lane margins (e.g., eye) for both time (e.g., eye width) and voltage (e.g., eye height) of the at least one I/O port. In such examples, the memory system controller may measure each lane of the at least one I/O port to obtain the eye pattern information for the at least one I/O port.

In some other examples, the memory system controller may measure each lane of the at least one I/O port and obtain eye pattern information that corresponds to each lane of the at least one I/O port. In some examples, the memory system controller may measure the lanes of each I/O port established between the memory system controller and the host system. In such examples, the memory system controller may obtain eye pattern information (e.g., a single eye width and a single eye height) that corresponds to all the I/O ports between the memory system controller and the host system.

At 215, the memory system controller may compare the eye pattern information obtained at 210 with one or more thresholds. For example, the memory system controller may determine whether the eye width satisfies (e.g., is greater than or equal to) an eye width threshold (e.g., such as a time threshold) or whether the eye height satisfies an eye height threshold (e.g., such as a voltage peak-to-peak or amplitude threshold). If the eye width or the eye height satisfy the threshold, then the memory system controller may proceed to operations 220 and 225. Alternatively, if the eye width and the eye height both fail to satisfy (e.g., are less than) the respective thresholds, the memory system controller may end the process flow 200 (e.g., the lanes of the at least one I/O may be faulty leading to additional correction).

At 220, the memory system controller may identify a sampling time for the lanes of the at least one I/O port based on the eye width. Similarly, at 225, the memory system controller may identify a reference voltage for the lanes of the at least one I/O port based on the eye height. For example, the combination of the sampling time and the reference voltage may be referred to as a margin sampling point. Accordingly, the memory system controller may, at operation 220, center the margin sampling point in the time domain based on the eye width. Similarly, at operation 225, the memory system controller may center the margin sampling point in the voltage domain based on the eye height. In this way, by centering the margin sampling point according to the eye pattern information, the memory system controller may identify the reference voltage and the sampling time for reading signals over the lanes of the at least one I/O. At 230, the memory system controller may monitor link recovery procedures over the at least one I/O port. The memory system controller may initiate a link recovery procedure in response to one or more errors occurring over the at least one I/O port, where such errors may be decoding errors, framing errors, loss of symbol lock, loss of block alignment, buffer overflow, buffer underflow, loss of lane-to-lane de-skew, or a combination thereof. Accordingly, during the link recovery procedure, the memory system controller may send and receive training sequences (TSs) in order to recover the link at the I/O port. For example, the memory system controller and the host system may communicate one or more first TS ordered sets (e.g., TS1 ordered sets) and one or more second TS ordered sets (e.g., TS2 ordered sets), where the first and second ordered sets include parameters used to re-establish the link between the memory system controller and the host system.

Accordingly, the memory system controller may account for, during a first duration, a quantity of link recovery procedures performed at the at least one I/O port, for example, by incrementing a link recovery counter by one each time a link recovery procedure has been performed. In such examples, the first duration may be one or more unit intervals (e.g., a regular time interval set by the memory system controller). As an illustrative example, during a first unit interval (e.g., first duration), the memory system controller may monitor the at least one I/O port and increment the link recovery counter for each link recovery procedure performed during the unit interval.

At 235, in response to monitoring the link recovery procedures during the first duration, the memory system controller may compare the quantity of link recovery procedures performed at the least one I/O port with a threshold. If the quantity of link recovery procedures performed during the first duration satisfies the threshold, the memory system controller may proceed to operation 240. Alternatively, if the quantity of link recovery procedures performed during the first duration fails to satisfy (e.g., is less than) the threshold, the memory system controller may proceed to monitor for link recovery procedures at operation 230.

The threshold may be a programmable threshold (e.g., user configurable) and stored in a mode register of the memory system. In such examples, if a relatively smaller threshold is selected, the memory system controller may be configured to initiate the lane margining procedure at an increased rate (e.g., the lane margining procedure is more sensitive to the link recovery procedures). While if a relatively larger threshold is selected, the memory system controller may be configured to initiate the lane margining procedure at a decreased rate (e.g., the lane margining procedure is less sensitive to the link recovery procedures).

At 240, based on the quantity of link recovery procedures identified during the first duration satisfying the threshold, the memory system controller may determine a rate of change between the quantity of link recovery procedures performed during the first duration and at least a second quantity of link recovery procedures performed during at least a second duration, where the second duration is subsequent in time to the first duration. That is, the memory system controller may measure the rate of change based on a quantity of link recovery procedures performed during one or more second durations that are subsequent in time to the first duration (e.g., a first differential).

For example, in response to determining that the quantity of link recovery procedures during the first duration satisfies the threshold, the memory system controller may also account for (e.g., keep track of) at least a second quantity of link recovery procedures performed during at least a second duration that is subsequent in time to the first duration. In such examples, to determine the rate of change, the memory system controller may perform a differential computation between the first quantity of link recovery procedures and the at least second quantity of link recovery procedures.

At 245, in response to determining the rate of change, the memory system controller may determine whether the rate of change is increasing. In such examples, the memory system controller may determine whether the output of the differential computation between the first quantity of link recovery procedures and the at least second quantity of link recovery procedures is increasing. Accordingly, if the rate of change is increasing, the memory system controller may proceed to operation 250. Alternatively, if the rate of change is stagnant or decreasing, the memory system controller may proceed to monitor the link recovery procedures at operation 230.

As an illustrative example, in response to determining that the quantity of link recovery procedures performed during the first unit interval (e.g., first duration) has satisfied the threshold, the memory system controller may monitor five additional unit intervals (e.g., second durations) that are subsequent in time to the first unit interval in order to obtain the rate of change. In such examples, the memory system controller may monitor each of the five additional unit intervals and identify five quantities of link recovery procedures, each of the five quantity of link recovery procedures being identified during a respective unit interval. The memory system controller may then determine a rate of change of the quantity of link recovery procedures performed across the first unit interval and the five additional unit intervals using a first order differential computation with respect to time.

For example, the memory system controller may determine, at operation 230, that 15 link recovery procedures were performed during the first time interval. Additionally, the memory system controller may determine that 20 link recovery procedures were performed during the first of the five additional unit intervals, that 23 link recovery procedures were performed during the second of the five additional unit intervals, that 24 link recovery procedures were performed during the third of the five additional unit intervals, that 26 link recovery procedures were performed during the fourth of the five additional unit intervals, and that 28 link recovery procedures were performed during the fifth of the five additional unit intervals. At operation 240 and 245, the memory system controller may determine the rate of change between the quantity of link recovery procedures identified during first unit interval (e.g., first duration) and the five additional quantities of link recovery procedures identified during the 5 additional unit intervals (e.g., second durations) is increasing (e.g., 15 to 20 to 23 to 24 to 26 to 28). Accordingly, the memory system controller may proceed to operation 250. Although described as five additional unit intervals, the memory system controller may monitor any quantity of additional unit intervals in response to the quantity of link recovery procedures identified during the first unit interval satisfying the threshold.

At 250, in response to determining that the rate of change is increasing, the memory system controller may initiate the lane margining procedure. For example, the memory system controller may measure, at 210, the eye pattern information for the at least one I/O port, determine, at 215, whether the eye pattern information satisfies the respective thresholds, identify, at 220, the sampling time (e.g., a time during a unit interval to sample signals) for reading signals over the at least one I/O port, and identify, at 225, the reference voltage for reading signals over the at least one I/O port. In this way, the memory system controller may initiate the lane margining procedure according to a quantity of link recovery procedures performed over the at least one I/O port.

As an illustrative example of process flow 200, the memory system may be connected with the host system via peripheral component interconnect (PCI) express (PCIe) I/O ports, which may facilitate high-speed data transfer between the memory system and the host system. Accordingly, in such examples, the memory system controller may perform the lane margining procedure 206 for the PCIe I/O ports established between the memory system and the host system in response to a power cycle at 205. For example, the memory system controller may measure the eye pattern information for the lanes of the at least one PCIe I/O port at 210, compare the measured eye pattern information for the at least one PCIe I/O port with one or more thresholds at 215, identify the sampling time for signals transmitted over the at least one PCIe I/O port at 220, and identify the reference voltage to be used to read signals over the least one PCIe I/O port.

Based on performing the initial lane margining procedure 206, the memory system controller may monitor and account for link recovery procedures that occur over the at least one PCIe I/O port during a first unit interval (e.g., duration) at 230, compare the quantity of link recover procedures that occurred over the at least one PCIe I/O port during the first unit interval with a threshold at 235, determine a rate of change of the quantity of link recover procedures over the at least one PCIe I/O port during one or more subsequent unit intervals at 240, and determine whether the rate of change of link recover procedures over the at least one PCIe I/O port is increasing at 245. In such examples, if the memory system controller determines that the rate of change is increasing, then the memory system controller may initiate the lane margining procedure 206 for the at least one PCIe I/O port.

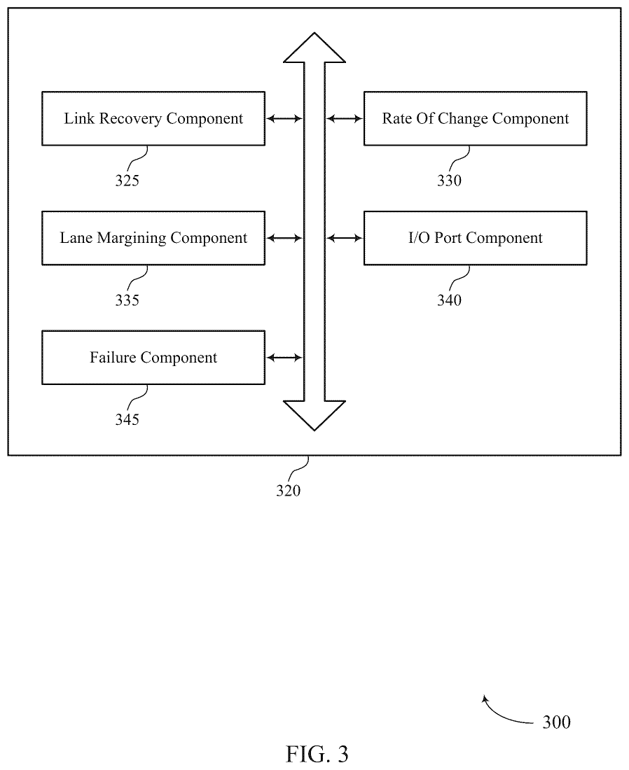

FIG. 3 shows a block diagram 300 of a memory system 320 that supports triggering lane margining in accordance with examples as disclosed herein. The memory system 320 may be an example of aspects of a memory system as described with reference to FIGS. 1 through 2. The memory system 320, or various components thereof, may be an example of means for performing various aspects of triggering lane margining as described herein. For example, the memory system 320 may include a link recovery component 325, a rate of change component 330, a lane margining component 335, an I/O port component 340, a failure component 345, or any combination thereof. Each of these components, or components of subcomponents thereof (e.g., one or more processors, one or more memories), may communicate, directly or indirectly, with one another (e.g., via one or more buses).

The link recovery component 325 may be configured as or otherwise support a means for performing, during a first duration, a first quantity of link recovery procedures on at least one I/O port established between the memory system and a host system. The rate of change component 330 may be configured as or otherwise support a means for determining, based at least in part on the first quantity of link recovery procedures satisfying a threshold, a rate of change between the first quantity of link recovery procedures and at least a second quantity of link recovery procedures, where the at least second quantity of link recovery procedures is identified over a second duration that is subsequent in time to the first duration. The lane margining component 335 may be configured as or otherwise support a means for initiating a lane margining procedure in response to the rate of change between the first quantity of link recovery procedures and the at least second quantity of link recovery procedures increasing.

In some examples, the I/O port component 340 may be configured as or otherwise support a means for monitoring, during the first duration, communications over the at least one I/O port established between the memory system and the host system. In some examples, the failure component 345 may be configured as or otherwise support a means for identifying one or more failures in the communications over the at least one I/O port, where performing the first quantity of link recovery procedures is based at least in part on identifying the one or more failures.

In some examples, to support determining the rate of change, the rate of change component 330 may be configured as or otherwise support a means for performing a differential computation between the first quantity of link recovery procedures and the at least second quantity of link recovery procedures.

In some examples, the link recovery component 325 may be configured as or otherwise support a means for determining that the first quantity of link recovery procedures satisfies the threshold, where determining the rate of change is based at least in part on the determination.

In some examples, to support lane margining procedure, the lane margining component 335 may be configured as or otherwise support a means for measuring eye pattern information of the at least one I/O port established between the memory system and the host system, the eye pattern information including an eye width and an eye height of the at least one I/O port. In some examples, to support lane margining procedure, the lane margining component 335 may be configured as or otherwise support a means for determining that the eye width of the least one I/O port satisfies an eye width threshold, that the eye height of the least one I/O port satisfies an eye height threshold, or both.

In some examples, to support lane margining procedure, the lane margining component 335 may be configured as or otherwise support a means for identifying a time during a unit interval to sample signals received from the at least one I/O port based at least in part on the eye width satisfying the eye width threshold.

In some examples, to support lane margining procedure, the lane margining component 335 may be configured as or otherwise support a means for identifying a reference voltage to compare with a sampled value of signals received from the at least one I/O port based at least in part on the eye height satisfying the eye height threshold.

In some examples, the eye width includes a time domain metric associated with signals transmitted over the at least one I/O port, and the eye height includes a voltage metric associated with the signals transmitted over the at least one I/O port.

In some examples, the threshold includes a user-programmable threshold.

In some examples, the threshold is stored in a mode register of the memory system.

In some examples, the memory system includes a solid state drive.

In some examples, the described functionality of the memory system 320, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 320, or various components thereof, may be implemented at least in part by instructions (e.g., stored in memory, non-transitory computer-readable medium) executable by such at least one processor.

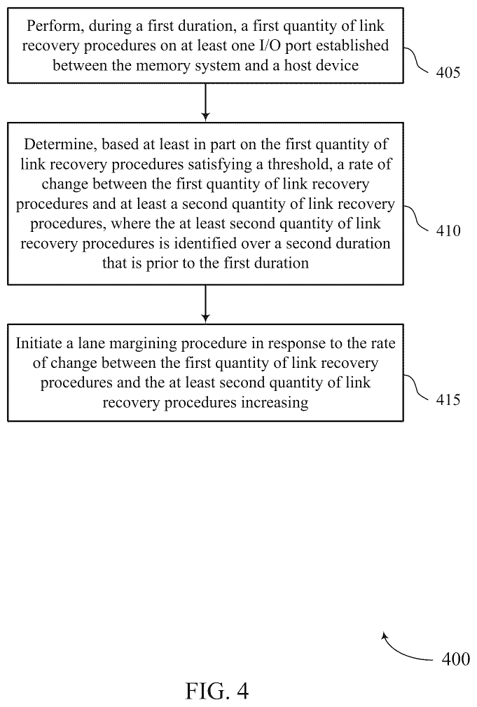

FIG. 4 shows a flowchart illustrating a method 400 that supports triggering lane margining in accordance with examples as disclosed herein. The operations of method 400 may be implemented by a memory system or its components as described herein. For example, the operations of method 400 may be performed by a memory system as described with reference to FIGS. 1 through 3. In some examples, a memory system may execute a set of instructions to control the functional elements of the device to perform the described functions. Additionally, or alternatively, the memory system may perform aspects of the described functions using special-purpose hardware.

At 405, the method may include performing, during a first duration, a first quantity of link recovery procedures on at least one I/O port established between the memory system and a host system. In some examples, aspects of the operations of 405 may be performed by a link recovery component 325 as described with reference to FIG. 3.

At 410, the method may include determining, based at least in part on the first quantity of link recovery procedures satisfying a threshold, a rate of change between the first quantity of link recovery procedures and at least a second quantity of link recovery procedures, where the at least second quantity of link recovery procedures is identified over a second duration that is subsequent in time to the first duration. In some examples, aspects of the operations of 410 may be performed by a rate of change component 330 as described with reference to FIG. 3.

At 415, the method may include initiating a lane margining procedure in response to the rate of change between the first quantity of link recovery procedures and the at least second quantity of link recovery procedures increasing. In some examples, aspects of the operations of 415 may be performed by a lane margining component 335 as described with reference to FIG. 3.

In some examples, an apparatus as described herein may perform a method or methods, such as the method 400. The apparatus may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for performing, during a first duration, a first quantity of link recovery procedures on at least one I/O port established between the memory system and a host system; determining, based at least in part on the first quantity of link recovery procedures satisfying a threshold, a rate of change between the first quantity of link recovery procedures and at least a second quantity of link recovery procedures, where the at least second quantity of link recovery procedures is identified over a second duration that is subsequent in time to the first duration; and initiating a lane margining procedure in response to the rate of change between the first quantity of link recovery procedures and the at least second quantity of link recovery procedures increasing.
Aspect 2: The method, apparatus, or non-transitory computer-readable medium of aspect 1, further including operations, features, circuitry, logic, means, or instructions, or any combination thereof for monitoring, during the first duration, communications over the at least one I/O port established between the memory system and the host system and identifying one or more failures in the communications over the at least one I/O port, where performing the first quantity of link recovery procedures is based at least in part on identifying the one or more failures.
Aspect 3: The method, apparatus, or non-transitory computer-readable medium of any of aspects 1 through 2, where determining the rate of change includes operations, features, circuitry, logic, means, or instructions, or any combination thereof for performing a differential computation between the first quantity of link recovery procedures and the at least second quantity of link recovery procedures.
Aspect 4: The method, apparatus, or non-transitory computer-readable medium of any of aspects 1 through 3, further including operations, features, circuitry, logic, means, or instructions, or any combination thereof for determining that the first quantity of link recovery procedures satisfies the threshold, where determining the rate of change is based at least in part on the determination.
Aspect 5: The method, apparatus, or non-transitory computer-readable medium of any of aspects 1 through 4, where the lane margining procedure includes operations, features, circuitry, logic, means, or instructions, or any combination thereof for measuring the at least one I/O port to obtain eye pattern information, the eye pattern information including an eye width and an eye height of the at least one I/O port and determining that the eye width of the least one I/O port satisfies an eye width threshold, that the eye height of the least one I/O port satisfies an eye height threshold, or both.
Aspect 6: The method, apparatus, or non-transitory computer-readable medium of aspect 5, where the lane margining procedure further includes operations, features, circuitry, logic, means, or instructions, or any combination thereof for identifying a time during a unit interval to sample signals received from the at least one I/O port based at least in part on the eye width satisfying the eye width threshold.
Aspect 7: The method, apparatus, or non-transitory computer-readable medium of any of aspects 5 through 6, where the lane margining procedure further includes operations, features, circuitry, logic, means, or instructions, or any combination thereof for identifying a reference voltage to compare with a sampled value of signals received from the at least one I/O port based at least in part on the eye height satisfying the eye height threshold.
Aspect 8: The method, apparatus, or non-transitory computer-readable medium of any of aspects 5 through 7, where the eye width includes a time domain metric associated with signals transmitted over the at least one I/O port, and the eye height includes a voltage metric associated with the signals transmitted over the at least one I/O port.
Aspect 9: The method, apparatus, or non-transitory computer-readable medium of any of aspects 1 through 8, where the threshold includes a user-programmable threshold.
Aspect 10: The method, apparatus, or non-transitory computer-readable medium of any of aspects 1 through 9, where the threshold is stored in a mode register of the memory system.
Aspect 11: The method, apparatus, or non-transitory computer-readable medium of any of aspects 1 through 10, where the memory system includes a solid state drive.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
perform, during a first duration, a first quantity of link recovery procedures on at least one input/output (I/O) port established between the memory system and a host system;
determine, based at least in part on the first quantity of link recovery procedures satisfying a threshold, a rate of change between the first quantity of link recovery procedures and at least a second quantity of link recovery procedures, wherein the at least second quantity of link recovery procedures is identified over a second duration that is subsequent in time to the first duration; and
initiate a lane margining procedure in response to the rate of change between the first quantity of link recovery procedures and the at least second quantity of link recovery procedures increasing.

2. The memory system of claim 1, wherein the processing circuitry is further configured to cause the memory system to:
monitor, during the first duration, communications over the at least one I/O port established between the memory system and the host system; and
identify one or more failures in the communications over the at least one I/O port, wherein performing the first quantity of link recovery procedures is based at least in part on identifying the one or more failures.

3. The memory system of claim 1, wherein, to determine the rate of change, the processing circuitry is configured to cause the memory system to:
perform a differential computation between the first quantity of link recovery procedures and the at least second quantity of link recovery procedures.

4. The memory system of claim 1, wherein the processing circuitry is further configured to cause the memory system to:
determine that the first quantity of link recovery procedures satisfies the threshold, wherein determining the rate of change is based at least in part on the determination.

5. The memory system of claim 1, wherein, to perform the lane margining procedure, the processing circuitry is configured to cause the memory system to:
measure the at least one I/O port to obtain eye pattern information, the eye pattern information comprising an eye width and an eye height of the at least one I/O port; and
determine that the eye width of the least one I/O port satisfies an eye width threshold, that the eye height of the least one I/O port satisfies an eye height threshold, or both.

6. The memory system of claim 5, wherein, to perform the lane margining procedure, the processing circuitry is configured to cause the memory system to:
identify a time during a unit interval to sample signals received from the at least one I/O port based at least in part on the eye width satisfying the eye width threshold.

7. The memory system of claim 5, wherein, to perform the lane margining procedure, the processing circuitry is configured to cause the memory system to:
identify a reference voltage to compare with a sampled value of signals received from the at least one I/O port based at least in part on the eye height satisfying the eye height threshold.

8. The memory system of claim 5, wherein the eye width comprises a time domain metric associated with signals transmitted over the at least one I/O port, and the eye height comprises a voltage metric associated with the signals transmitted over the at least one I/O port.

9. The memory system of claim 1, wherein the threshold comprises a user-programmable threshold.

10. The memory system of claim 1, wherein the threshold is stored in a mode register of the memory system.

11. The memory system of claim 1, wherein the memory system comprises a solid state drive.

12. A method at a memory system, comprising:
performing, during a first duration, a first quantity of link recovery procedures on at least one input/output (I/O) port established between the memory system and a host system;
determining, based at least in part on the first quantity of link recovery procedures satisfying a threshold, a rate of change between the first quantity of link recovery procedures and at least a second quantity of link recovery procedures, wherein the at least second quantity of link recovery procedures is identified over a second duration that is subsequent in time to the first duration; and
initiating a lane margining procedure in response to the rate of change between the first quantity of link recovery procedures and the at least second quantity of link recovery procedures increasing.

13. The method of claim 12, further comprising:
monitoring, during the first duration, communications over the at least one I/O port established between the memory system and the host system; and
identifying one or more failures in the communications over the at least one I/O port, wherein performing the first quantity of link recovery procedures is based at least in part on identifying the one or more failures.

14. The method of claim 12, wherein determining the rate of change comprises:
performing a differential computation between the first quantity of link recovery procedures and the at least second quantity of link recovery procedures.

15. The method of claim 12, further comprising:
determining that the first quantity of link recovery procedures satisfies the threshold, wherein determining the rate of change is based at least in part on the determination.

16. The method of claim 12, wherein the lane margining procedure comprises:
measuring the at least one I/O port to obtain eye pattern information, the eye pattern information comprising an eye width and an eye height of the at least one I/O port; and
determining that the eye width of the least one I/O port satisfies an eye width threshold, that the eye height of the least one I/O port satisfies an eye height threshold, or both.

17. The method of claim 16, wherein the lane margining procedure further comprises:
identifying a time during a unit interval to sample signals received from the at least one I/O port based at least in part on the eye width satisfying the eye width threshold.

18. The method of claim 16, wherein the lane margining procedure further comprises:
identifying a reference voltage to compare with a sampled value of signals received from the at least one I/O port based at least in part on the eye height satisfying the eye height threshold.

19. The method of claim 16, wherein the eye width comprises a time domain metric associated with signals transmitted over the at least one I/O port, and the eye height comprises a voltage metric associated with the signals transmitted over the at least one I/O port.

20. The method of claim 12, wherein the threshold comprises a user-programmable threshold.

21. The method of claim 12, wherein the threshold is stored in a mode register of the memory system.

22. The method of claim 12, wherein the memory system comprises a solid state drive.

23. A non-transitory computer-readable medium storing code, the code comprising instructions executable by one or more processors to:
perform, during a first duration, a first quantity of link recovery procedures on at least one input/output (I/O) port established between a memory system and a host system;
determine, based at least in part on the first quantity of link recovery procedures satisfying a threshold, a rate of change between the first quantity of link recovery procedures and at least a second quantity of link recovery procedures, wherein the at least second quantity of link recovery procedures is identified over a second duration that is subsequent in time to the first duration; and
initiate a lane margining procedure in response to the rate of change between the first quantity of link recovery procedures and the at least second quantity of link recovery procedures increasing.

24. The non-transitory computer-readable medium of claim 23, wherein the instructions are further executable by the one or more processors to:
monitor, during the first duration, communications over the at least one I/O port established between the memory system and the host system; and
identify one or more failures in the communications over the at least one I/O port, wherein performing the first quantity of link recovery procedures is based at least in part on identifying the one or more failures.

25. The non-transitory computer-readable medium of claim 23, wherein the instructions to determine the rate of change are executable by the one or more processors to:
perform a differential computation between the first quantity of link recovery procedures and the at least second quantity of link recovery procedures.
